(19) United States
(12) Patent Application Publication
(10) Pub. No.: US 2012/0192928 A1
(43) Pub. Date: Aug. 2, 2012

(54) LAMINATED PV MODULE PACKAGE

(76) Inventors: Mark Francis Krol, Painted Post, NY (US); James Ernest Webb, Corning, NY (US)

(21) Appl. No.: 13/355,837

(22) Filed: Jan. 23, 2012

Related U.S. Application Data
(60) Provisional application No. 61/436,719, filed on Jan. 27, 2011.

(51) Int. Cl. H01L 31/048; B32B 7/02

(52) U.S. Cl. 136/251; 428/212; 428/215

(57) ABSTRACT

Laminated packages and photovoltaic modules having a glass substrate layer or a plurality of glass substrate layers encapsulated between top and bottom glass protective layers. The glass substrate layers can have similar CTE. Likewise, the top and bottom glass protective layers can have similar CTEs, CTEs that may be different from the CTE of the glass substrate layer or layers.

This application claims the benefit of priority under 35 U.S.C. §119 of U.S. Provisional Application Ser. No. 61/436719 filed on Jan. 27, 2011 the content of which is relied upon and incorporated herein by reference in its entirety.

### BACKGROUND

1. Field

Embodiments relate generally to laminated glass packages, and more particularly to laminated glass packages useful, for example, for thin film or wafered photovoltaic modules.

2. Technical Background

Photovoltaic modules are used to convert sunlight into electricity. Two major types used or in development today are wafered modules using multiple silicon wafers connected together and thin film modules using cadmium telluride (CdTe), copper indium gallium di-selenide (CIGS) or thin film (amorphous and microcrystalline) silicon. Typical packages 100 for the wafered modules have one protective glass layer 10 such as soda lime, a polymer backsheet 12, silicon wafers 16 and encapsulant layers 20 between the protective glass layer and the backsheet, and an edge seal 18, a metal frame 14, and electrical contacts 22 as shown by the cross section in FIG. 1A. Typical packages 101 for thin film modules have two protective glass layers 10 such as soda lime, a thin film(s) 17, an encapsulant layer 20 between the two glass sheets, an edge seal 18, and electrical contacts 22 as shown by the cross section in FIG. 1B. Ethylene vinyl acetate (EVA), polyvinyl butyral (PVB) or other encapsulants are commonly used to bond the two sheets together. Sealing materials such as a butyl sealant at the module perimeters are used to increase moisture resistance.

PV modules need to endure various environmental conditions that can cause stresses in the glass sheets. Modules are subjected to forces from wind, snow and hail. International Electrotechnical Commission (IEC) document 61646, “Thin-Film Terrestrial Photovoltaic (PV) Modules—Design Qualification and Type Approval,” states that a thin film photovoltaic module must withstand wind loads of 2400 Pa, snow loads of 5400 Pa, and impacts by 25 mm diameter ice balls projected in a direction perpendicular to the module face at a speed of 23 m/s (51 mph).

Embodiments described herein may provide solutions to minimize and potentially eliminate the described bowing resulting from lamination when using specialty glasses while also improving the module mechanical robustness.

### SUMMARY

This application describes a laminated glass package that is symmetric with respect to glass coefficient of thermal expansion (CTE) variations through the module package thickness. This package includes 3 or more layers of glass. Starting with the glass on the outside surface, it is ideally paired with a glass of the similar CTE on the other outside surface. The next layer of paired glasses is also ideally of similar CTE, but the CTE can be different than other pairs in the package. In instances where a center sheet of glass is used, this glass may have a CTE different from the CTE of the matched pairs of glass surrounding it. The laminated glass package may be a thin film photovoltaic module package with two sheets of soda lime silicate glasses on the module exterior acting as protective glass layers, wherein there is placed one or more glass substrate layers between the glass protective layers.

One embodiment is a laminated glass package comprising a glass substrate layer having a top surface and a bottom surface, a bottom glass protective layer, the bottom glass protective layer being laminated to the bottom surface of the glass substrate layer, and a top glass protective layer, the top glass protective layer being laminated to the top surface of the glass substrate layer, wherein the top glass protective layer and the bottom glass protective layer have similar coefficients of thermal expansion.

Another embodiment is a laminated glass package comprising a first glass substrate layer having a top surface and a bottom surface, a second glass substrate layer having a top surface and a bottom surface, a bottom glass protective layer, the bottom glass protective layer being laminated to the bottom surface of the second glass substrate layer, and a top glass protective layer, the top glass protective layer being laminated to the top surface of the first glass substrate layer, wherein the top glass protective layer and the bottom glass protective layer have similar coefficients of thermal expansion.

Another embodiment is a photovoltaic module comprising a glass substrate layer having a top surface and a bottom surface, a bottom glass protective layer, the bottom glass protective layer being laminated to the bottom surface of the glass substrate layer, a top glass protective layer, the top glass protective layer being laminated to the top surface of the glass substrate layer, and a photovoltaic functional material disposed between either the bottom surface or the top surface of the glass substrate layer and either the bottom or the top glass protective layer, wherein the top glass protective layer and the bottom glass protective layer have similar coefficients of thermal expansion.

A further embodiment is a photovoltaic module comprising a first glass substrate layer having a top surface and a bottom surface, a second glass substrate layer having a top surface and a bottom surface, a bottom glass protective layer, the bottom glass protective layer being laminated to the bottom surface of the second glass substrate layer, a top glass protective layer, the top glass protective layer being laminated to the top surface of the first glass substrate layer, and a photovoltaic functional material disposed between either the bottom surface of the first glass substrate layer or the top surface of the second glass substrate layer and either the bottom or the top glass protective layer, wherein the top glass protective layer and the bottom glass protective layer have similar coefficients of thermal expansion.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing figures.

FIG. 1A and FIG. 1B show conventional cross sectional schematics of wafered and thin film modules, respectively.

FIG. 2A and FIG. 2B show cross sectional schematics of the effect of CTE on bowing of a dual glass PV module.

FIG. 3 shows a cross sectional schematic of a laminated glass package, according to one embodiment.

FIG. 4 shows a cross sectional schematic of a PV module, according to one embodiment.

FIG. 5 shows a cross sectional schematic of a PV module, according to one embodiment.

FIG. 6 shows a cross sectional schematic of a laminated glass package, according to one embodiment.

FIG. 7 shows a cross sectional schematic of a PV module, according to one embodiment.

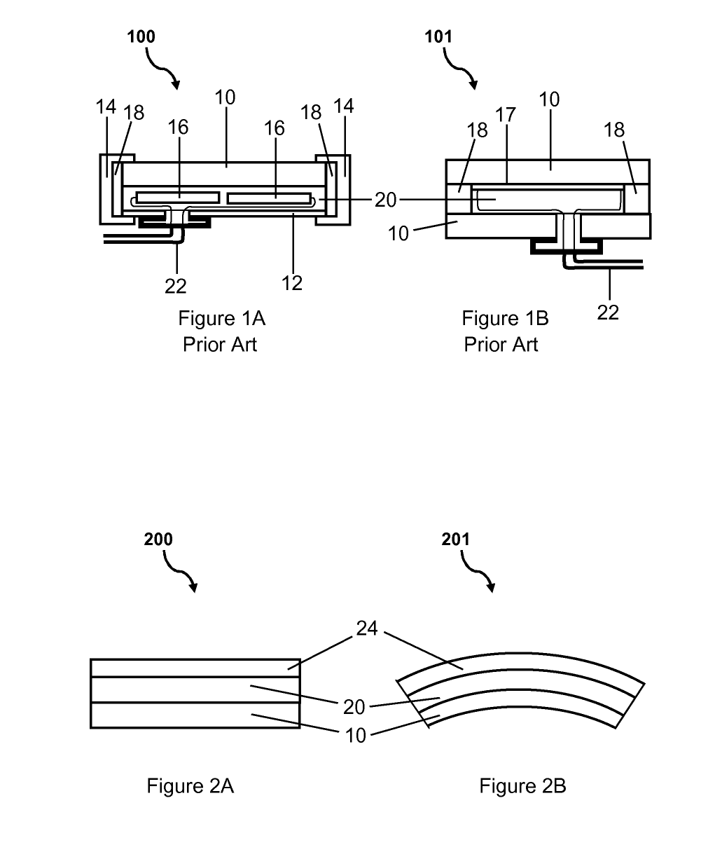

### DETAILED DESCRIPTION

Reference will now be made in detail to various embodiments of the invention, examples of which are illustrated in the accompanying drawings. Wherever possible, the same reference numbers will be used throughout the drawings to refer to the same or like parts.

As used herein, the term “specialty glass” is used to describe any glass layer having a chemical composition that is different than the chemical composition of common soda lime glass. Specialty glasses typically have CTE values over the range, but not limited to, 2 to 9 ppm/° C., for example, 3 to 9 ppm/° C., for example, 3 to 5 ppm/° C. and common soda lime glass has CTE values in the range of 8 to 9 ppm/° C.

Specialty glasses have been identified as an enabler to improving conversion efficiency. As a result of modifying the glass composition, the coefficient of thermal expansion (CTE) may not be equivalent to that of commonly used soda lime silicate glass. FIG. 2A and FIG. 2B show the effect of CTE on the flatness of a laminated module. Features 200 of a PV module are shown in FIG. 2A. If the CTE's of the glass sheet, such as a specialty glass sheet 24 and the other glass sheet, such as a soda lime glass sheet 10 are the same when laminated, for example, with an encapsulant layer 20, the module remains flat with minimum bow. If the CTE's of the specialty glass 24 and the other glass sheet, such as a soda lime glass sheet 10 are different when laminated, for example, with an encapsulant layer 20, the module is bowed to some degree dependent upon the magnitude of the CTE mismatch. The bowing results from the lamination process occurring at a higher temperature than the module use range. As a result the module is bowed toward the higher CTE glass, as shown in FIG. 2B. The maximum bow occurs at the coldest temperature the module experiences.

One embodiment is a laminated glass package comprising a glass substrate layer having a top surface and a bottom surface, a bottom glass protective layer, the bottom glass protective layer being laminated to the bottom surface of the glass substrate layer, and a top glass protective layer, the top glass protective layer being laminated to the top surface of the glass substrate layer, wherein the top glass protective layer and the bottom glass protective layer have similar coefficients of thermal expansion.

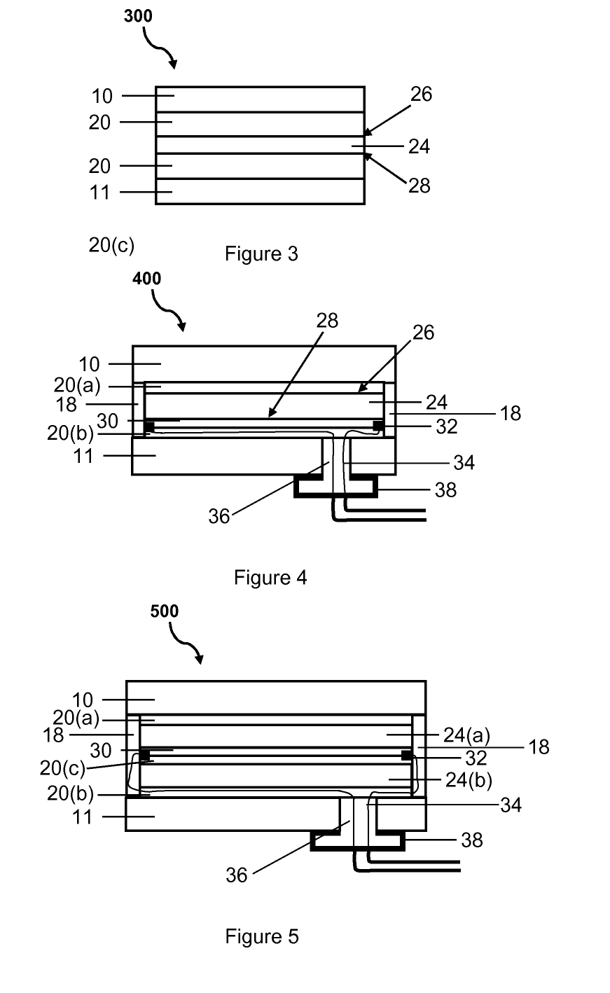

Herein is described a laminated glass package that is symmetric with respect to glass CTE variations through the module package thickness. FIG. 3 shows a cross sectional schematic of features of a laminated glass package 300, according to one embodiment. In this embodiment, the laminated glass package comprises a glass substrate layer 24 that has both a top surface 26 and a bottom surface 28.

The glass substrate layer may be a thin soda lime glass, or a specialty glass that has been engineered to have (a) a particular CTE different from soda lime glass; (b) a desirable chemical compositions; (c) engineered to have a high strain point; and/or (d) engineered to have some other desirable property that may enhance the performance of the glass. The glass substrate layer, for example, specialty glass layer can have a thickness of 1.5 mm or less, for example, 1.4 mm or less, for example, 1.3 mm or less, for example, 1.2 mm or less, for example, 1.1 mm or less, for example, 1.0 mm or less, for example, 0.9 mm or less, for example, 0.8 mm or less than, for example, 0.7 mm or less, for example, 0.6 mm or less, for example, 0.5 mm or less, or, for example, in the range of from 0.5 mm to 1.5 mm, for example, from 0.5 mm to 1.4 mm, for example, from 0.5 mm to 1.3 mm, for example, from 0.5 mm to 1.2 mm, for example, from 0.5 mm to 1.1 mm, for example, from 0.5 mm to 1.0 mm, or for example, from 0.05mm to 0.5 mm.

As shown in FIG. 3, the laminated glass package comprises a top protective glass layer 10 and a bottom protective glass layer 11, the bottom glass protective layer being laminated to the bottom surface of the glass substrate layer, and the top glass protective layer being laminated to the top surface of the glass substrate layer. In one embodiment, the top glass protective layer and the bottom glass protective layer have similar coefficients of thermal expansion.

In one embodiment, the protective glass layers are standard soda lime glass of a thickness sufficient to provide the mechanical damage resistance and other reliability requirements. FIG. 3 further describes encapsulant layers 20 interposed between the glass substrate layer 24 and the top and bottom glass protective layers 10 and 11.

The encapsulant layers may be an Ethylene-vinyl acetate (EVA) silicone-based material (e.g. STR PhotoCap® 0507P), or a polyvinyl butyral (PVB) silicone-based material (e.g. Kuraray Trisifol® Solar R40). These materials are used as a bonding material to bond adjacent glass sheets together. The encapsulant layers may also be of some other material known in the art that may have suitable characteristics such as adhesion or transmission. In one embodiment, the CTE of the top protective glass layer and the bottom protective glass layer are similar if not identical. The CTE of the glass substrate layer may be different from the CTE of the protective glass layers.

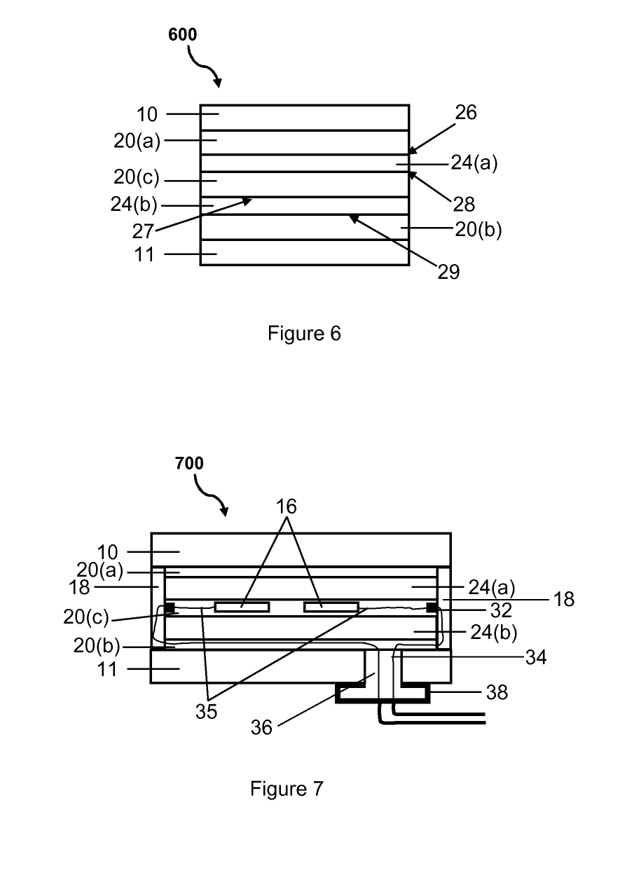

Another embodiment, features of which are shown in FIG. 6, is a laminated glass package 600 comprising a first glass substrate layer 24(a) having a top surface 26 and a bottom surface 28, a second glass substrate layer 24(b) having a top surface 27 and a bottom surface 29, a bottom glass protective layer 11, the bottom glass protective layer being laminated to the bottom surface of the second glass substrate layer, and a top glass protective layer 10, the top glass protective layer being laminated to the top surface of the first glass substrate layer, wherein the top glass protective layer and the bottom glass protective layer have similar coefficients of thermal expansion. The laminated glass package can further comprise a first encapsulation layer 20(a) interposed between the top surface of the first glass substrate layer and the top glass protective layer, and a second encapsulation layer 20(b) interposed between the bottom surface of the second glass substrate layer and the bottom glass protective layer. The laminated glass package may further comprise a third encapsulation layer 20(c) disposed between the first and second glass substrate layers.

Another embodiment is a photovoltaic module comprising a glass substrate layer having a top surface and a bottom surface, a bottom glass protective layer, the bottom glass protective layer being laminated to the bottom surface of the glass substrate layer, a top glass protective layer, the top glass protective layer being laminated to the top surface of the glass substrate layer, and a photovoltaic functional material disposed between either the bottom surface or the top surface of the glass substrate layer and either the bottom or the top glass protective layer, wherein the top glass protective layer and the bottom glass protective layer have similar coefficients of thermal expansion.

Features of a photovoltaic module 400 are shown by the cross sectional illustration shown in FIG. 4. Referring to FIG. 4, a photovoltaic module may comprise a laminated glass package such as the embodiment shown in FIG. 3. In one embodiment, the glass substrate layer 24 is a specialty glass. The material and thicknesses of the substrate layers may be as previously described above. It is conceivable that, depending upon the material and/or the thicknesses of the top protective glass layer 10 and the bottom protective glass layer 11, the glass substrate layer may be 0.5 mm or less. In one embodiment, encapsulant layers 20(a) and 20(b) are interposed between the glass substrate layer 24 and the top glass protective layer 10 and between the functional layer 30 and the bottom glass protective layers 11, respectively. Depending upon the material used for the encapsulant layers 20(a) and 20(b), an edge seal 18 may be advantageous. The edge seal is typically of a non-conductive butyl sealant material, and provides additional hermetic sealing to the module. A photovoltaic functional material 30 may be a cadmium telluride (CdTe) functional layer, a CIGS functional layer, a silicon-tandem (Si-Tandem) functional layer or even an amorphous silicon (a-Si) functional layer. Where the photovoltaic functional material 30 is CdTe, Si-Tandem or a-Si, the functional layer is disposed on and/or adhered to the bottom surface 28 of the glass substrate layer 24 (embodiment shown in FIG. 4). Where the photovoltaic functional material 30 is CIGS, then the functional layer is disposed on and/or adhered to the top surface 26 of the glass substrate layer 24. Attached to the functional layer are bus bars 32 and attached thereto are conducting ribbons 34.

In the case of silicon wafer based photovoltaic modules, where the photovoltaic functional material is silicon wafers, the silicon wafers and interconnecting electrodes and bus bases can be disposed in the encapsulant layer between the glass substrate layer 24 and bottom glass protective layer 12. In some embodiments, the silicon wafers are surrounded by the encapsulant layer.

The bottom protective glass layer 11, in one embodiment, is provided with a through via or feed through hole 36 to allow the ribbon connectors to pass through the bottom protective glass layer. Also as shown in FIG. 4, a junction box 38 is connected to the conducting ribbons and attached to the bottom surface of the bottom protective glass layer, also at the point of the feed through hole.

Further referring to FIG. 4, the top protective glass layer 10 and the bottom protective glass layer 11 may be made out of tempered soda lime glass of a thickness, for example, 1.5 mm or more, for example 2.0 mm or more. The protective glass layers provide the PV module with the required mechanical robustness against wind, snow, and hail. The encapsulant layers 20(a) and 20(b) are interposed between the glass substrate layer 24 and the top glass protective layer and between the functional layer 30 and the bottom glass protective layer, respectively. Depending upon the encapsulant layers 20(a) and 20(b) materials used, an edge seal 18 may be advantageous. The edge seal, for example, a perimeter seal is typically of a non-conductive butyl sealant material, and provides additional hermetic sealing to the module. As with the glass package, it is preferable for the CTE of the top protective glass layer and the bottom protective glass layer to be similar if not identical. The CTE of the glass substrate layer may be different from the CTE of the protective glass layers. This symmetric stacking of the top and bottom protective glass layers having similar CTEs, significantly reduces if not eliminates the lamination bow.

A further embodiment is a photovoltaic module comprising a first glass substrate layer having a top surface and a bottom surface, a second glass substrate layer having a top surface and a bottom surface, a bottom glass protective layer, the bottom glass protective layer being laminated to the bottom surface of the second glass substrate layer, a top glass protective layer, the top glass protective layer being laminated to the top surface of the first glass substrate layer, and a photovoltaic functional material disposed between either the bottom surface of the first glass substrate layer or the top surface of the second glass substrate layer and either the bottom or the top glass protective layer, wherein the top glass protective layer and the bottom glass protective layer have similar coefficients of thermal expansion.

Features of a photovoltaic module 500 and 700 are shown by the cross sectional illustrations shown in FIG. 5 and FIG. 7, respectively. In these embodiments, a plurality of glass substrate layers may be used. A first glass substrate layer 24(a) can be a thin specialty glass. The glass, for example, the specialty glass can have a thickness of 1.5 mm or less, for example, 1.4 mm or less, for example, 1.3 mm or less, for example, 1.2 mm or less, for example, 1.1 mm or less, for example, 1.0 mm or less, for example, 0.9 mm or less, for example, 0.8 mm or less than, for example, 0.7 mm or less, for example, 0.6 mm or less, for example, 0.5 mm or less, or, for example, in the range of from 0.5 mm to 1.5 mm, for example, from 0.5 mm to 1.4 mm, for example, from 0.5 mm to 1.3 mm, for example, from 0.5 mm to 1.2 mm, for example, from 0.5 mm to 1.1 mm, for example, from 0.5 mm to 1.0 mm, or for example, from 0.05mm to 0.5 mm. A photovoltaic functional material 30 is disposed between either the bottom surface of the first glass substrate layer or the top surface of the second glass substrate layer and either the bottom or the top glass protective layer or, in some embodiments, attached to the bottom surface of the first glass substrate layer 24(a) as described above for CdTe, a-Si, and Si-Tandem as shown in FIG. 5. Attached to the photovoltaic functional material are the bus bars 32 and attached thereto are the conducting ribbons 34. A second glass substrate layer 24(b), which in one embodiment is a matched glass to the first glass substrate layer 24(a), namely a similar specialty glass having a similar CTE, is attached to the first glass substrate layer via the use of an encapsulant layer 20(c). In the case of CIGS, the functional layer, bus bars, and conducting ribbons are disposed on the top surface of the second glass substrate layer 24(b). In the case of silicon wafer based modules as shown in FIG. 7, the silicon wafers 16 and interconnecting electrodes 35 and bus bars 32 can be disposed in the encapsulant layer 20(c) between the first glass substrate layer and second glass substrate layer. Top and bottom protective glass layers, 10 and 11 respectively, are provided to enclose the matched specialty glass layers. The photovoltaic module can further comprise a first encapsulation layer 20(a) interposed between the top surface of the first glass substrate layer and the top glass protective layer, and a second encapsulation layer 20(b) interposed between the bottom surface of the second glass substrate layer and the bottom glass protective layer. The laminated glass package may further comprise a third encapsulation layer 20(c) disposed between the first and second glass substrate layers.

Further encapsulant layers 20 are employed to adhere the first glass substrate layer 24(a) to the top protective layer 10, and the second glass substrate layer 24(b) to the bottom protective layer 11. As previously described, the bottom protective glass layer has a feed through hole 36 to allow the ribbon connectors 34 to pass through the bottom protective glass layer 11. In one embodiment, the top protective glass layer and the bottom protective glass layer can be tempered soda lime glass, for example, of a thickness 3.2 mm or less, for example, 2 mm or less, or, for example, 1.5 mm or more, or for example, 1.5 mm to 3.2 mm. In some embodiments, the protective glass layers can have a thickness of 1.5 mm or less, for example, 1.4 mm or less, for example, 1.3 mm or less, for example, 1.2 mm or less, for example, 1.1 mm or less, for example, 1.0 mm or less, for example, 0.9 mm or less, for example, 0.8 mm or less than, for example, 0.7 mm or less, for example, 0.6 mm or less, for example, 0.5 mm or less, or, for example, in the range of from 0.5 mm to 1.5 mm, for example, from 0.5 mm to 1.4 mm, for example, from 0.5 mm to 1.3 mm, for example, from 0.5 mm to 1.2 mm, for example, from 0.5 mm to 1.1 mm, for example, from 0.5 mm to 1.0 mm, or for example, from 0.05mm to 0.5 mm. Further, the top protective glass layer and the bottom protective glass layer, in one embodiment, are the same material and have similar if not identical CTEs. As shown in FIG. 5 and FIG. 7, an edge seal 18 is used to further encapsulate the module. The edge seal 18 is placed between the top protective layer 10 and the bottom protective layer 11, thereby fully enclosing the glass substrate layers. The CTE of the glass substrate layers may be different from the CTE of the protective glass layers. This symmetric stacking of the top and bottom protective glass layers both having similar CTEs, surrounding a matched CTE pair of glass substrate layers, significantly reduces if not eliminates the lamination bow. To complete the photovoltaic module, also as shown in FIG. 5 and FIG. 7, the junction box 38 is connected to the conducting ribbons and attached to the bottom surface of the bottom protective glass layer, also at the point of the feed through hole 36.

In the embodiments described herein, the glass substrate layers can be specialty glasses having CTE values over the range, but not limited to, 2 to 9 ppm/° C., for example, 3 to 9 ppm/° C., for example, 3 to 5 ppm/° C. and the glass protective layers can be common soda lime glass having CTE values in the range of 8 to 9 ppm/° C. The glass protective layers can be either strengthened or tempered glass, for example, strengthened or tempered soda lime. In some embodiments, the glass substrate layers and the protective glass layers can have the same CTE. In one embodiment, soda lime glass is the top and bottom protective layers with a CTE of from 8 to 9 ppm/° C. and the glass substrate layer(s) is a specialty glass with a CTE of from 3.1 to 4.5 ppm/° C.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. A laminated glass package comprising:
a glass substrate layer having a top surface and a bottom surface;
a bottom glass protective layer, the bottom glass protective layer being laminated to the bottom surface of the glass substrate layer; and
a top glass protective layer, the top glass protective layer being laminated to the top surface of the glass substrate layer,
wherein the top glass protective layer and the bottom glass protective layer have similar coefficients of thermal expansion.

2. The package according to claim 1, wherein the glass substrate layer has a thickness of 1.5 mm or less.

3. The package according to claim 1, wherein the top and bottom glass protective layers each have a thickness of 1.5 mm or more.

4. The package according to claim 1, wherein the glass substrate layer has a coefficient of thermal expansion which is different than the coefficients of thermal expansion of the top and bottom glass protective layers.

5. The package according to claim 4, wherein the glass substrate layer is a specialty glass.

6. The package according to claim 1, wherein the top and bottom glass protective layers are both a soda lime glass.

7. The package according to claim 1, further comprising:
a first encapsulation layer adhered to the top surface of the glass substrate layer; and
a second encapsulation layer adhered to the bottom surface of the glass substrate layer.

8. A laminated glass package comprising:
a first glass substrate layer having a top surface and a bottom surface;
a second glass substrate layer having a top surface and a bottom surface;
a bottom glass protective layer, the bottom glass protective layer being laminated to the bottom surface of the second glass substrate layer; and
a top glass protective layer, the top glass protective layer being laminated to the top surface of the first glass substrate layer,
wherein the top glass protective layer and the bottom glass protective layer have similar coefficients of thermal expansion.

9. The package according to claim 8, wherein the first glass substrate layer and the second glass substrate layer have similar coefficients of thermal expansion.

10. The package according to claim 8, further comprising:
a first encapsulation layer interposed between the top surface of the first glass substrate layer and the top glass protective layer; and
a second encapsulation layer interposed between the bottom surface of the second glass substrate layer and the bottom glass protective layer.

11. A photovoltaic module comprising:
a glass substrate layer having a top surface and a bottom surface;
a bottom glass protective layer, the bottom glass protective layer being laminated to the bottom surface of the glass substrate layer;
a top glass protective layer, the top glass protective layer being laminated to the top surface of the glass substrate layer; and
a photovoltaic functional material disposed between either the bottom surface or the top surface of the glass substrate layer and either the bottom or the top glass protective layer,
wherein the top glass protective layer and the bottom glass protective layer have similar coefficients of thermal expansion.

12. The module according to claim 11, wherein the photovoltaic functional material comprises a thin film photovoltaic layer or a silicon wafer.

13. The module according to claim 11, further comprising:
a first encapsulation layer interposed between the top surface of the glass substrate layer and the top glass protective layer; and
a second encapsulation layer interposed between the bottom surface of the glass substrate layer and the bottom glass protective layer.

14. The module according to claim 13, further comprising:
an edge seal, sealingly attached to the top glass protective layer and to the bottom glass protective layer, enclosing therein the glass substrate layer having the functional layer thereon and the first and second encapsulation layers.

15. The module according to claim 11, wherein the glass substrate layer has a thickness of 1.5 mm or less.

16. The module according to claim 11, wherein the top and bottom glass protective layers each have a thickness of 1.5 mm or more.

17. The module according to claim 11, wherein the glass substrate layer has a coefficient of thermal expansion which is different than the coefficients of thermal expansion of the top and bottom glass protective layers.

18. A photovoltaic module comprising:
a first glass substrate layer having a top surface and a bottom surface;
a second glass substrate layer having a top surface and a bottom surface;
a bottom glass protective layer, the bottom glass protective layer being laminated to the bottom surface of the second glass substrate layer;
a top glass protective layer, the top glass protective layer being laminated to the top surface of the first glass substrate layer; and
a photovoltaic functional material disposed between either the bottom surface of the first glass substrate layer or the top surface of the second glass substrate layer and either the bottom or the top glass protective layer,
wherein the top glass protective layer and the bottom glass protective layer have similar coefficients of thermal expansion.

19. The module according to claim 18, wherein the photovoltaic functional material comprises a thin film photovoltaic layer or a silicon wafer.

20. The module according to claim 18, further comprising:
a plurality of encapsulation layers interposed between the top and bottom glass protective layers and the first and second glass substrate layers.

21. The module according to claim 18, further comprising:
an edge seal, sealingly attached to the top glass protective layer and to the bottom glass protective layer, enclosing therein the first and second glass substrate layers and the plurality of encapsulation layers.

22. The module according to claim 18, wherein the first and second glass substrate layers have similar coefficients of thermal expansion.

23. The module according to claim 18, wherein the first glass substrate layer and the second glass substrate layers both have thicknesses of less than 1.5 mm.

24. The module according to claim 18, wherein the top and bottom glass protective layers each have a thickness of 1.5 mm or more.

25. The module according to claim 18, wherein the first and second glass substrate layers are a specialty glass having a coefficient of thermal expansion that is not equal to the coefficient of thermal expansion of the top and bottom glass protective layers.
